(19) United States
(12) Patent Application Publication
(10) Pub. No.: US 2022/0045679 A1
(43) Pub. Date: Feb. 10, 2022

(54) SPDT SWITCH FOR IMPROVING POWER TRANSFER CAPABILITY

(71) Applicant: ELECTRONICS AND TELECOMMUNICATIONS RESEARCH INSTITUTE, Daejeon (KR)

(72) Inventors: Youn Sub NOH, Daejeon (KR); Soo Cheol KANG, Daejeon (KR); Seong Il KIM, Daejeon (KR); Hae Cheon KIM, Daejeon (KR); Ho Kyun AHN, Daejeon (KR); Sang Heung LEE, Daejeon (KR); Jong Won LIM, Daejeon (KR); Sung Jae CHANG, Daejeon (KR); Hyun Wook JUNG, Daejeon (KR)

(21) Appl. No.: 17/396,221

(22) Filed: Aug. 6, 2021

(30) Foreign Application Priority Data
Aug. 7, 2020 (KR) 10-2020-0099524
Jul. 19, 2021 (KR) 10-2021-0094394

(51) Int. Cl. H03K 17/687

(52) U.S. Cl. CPC H03K 17/6874

(57) ABSTRACT

Provided is a single pole double through (SPDT) switch including a series switching unit including first and second series switching elements commonly connected to a common input port, and a shunt switching unit including a plurality of shunt switching elements connected in parallel to a first signal path connecting the common input port to a first output port and a second signal path connecting the common input port to a second output port, wherein first and second inductors are respectively connected to gate terminals of the first and second series switching elements.

### CROSS-REFERENCE TO RELATED APPLICATIONS

This application claims priority under 35 U.S.C. § 119 to Korean Patent Application No. 10-2020-0099524, filed on Aug. 7, 2020 and Korean Patent Application No. 10-2021-0094394, filed on Jul. 19, 2021, the disclosure of which is incorporated herein by reference in its entirety.

### TECHNICAL FIELD

The present invention relates to a single pole double through (SPDT) switch, and more particularly, to a technology related to improvement of power transfer capability.

### BACKGROUND

A typical SPDT switch uses a field effect transistor (FET)-based device. In designing an SPDT switch, a FET element with a large area is usually used as a series switching element to reduce insertion loss and an FET element with a relatively small area is used as a switching element connected in parallel with the series switching element, to improve isolation characteristics.

In the SPDT switch, a gate terminal of each switching element is used as a control terminal, and a drain terminal and a source terminal are used as a path for transmitting an RF signal. Here, a resistor having a large resistance value of several kΩ is connected to the gate terminal to prevent an RF signal from being transmitted in a direction of the control terminal.

Meanwhile, in the case of using a gallium nitride (GaN)-based switching element to design the SPDT switch, a gate leakage current increases as an RF signal increases, unlike a gallium arsenide (GaAs)-based switching element.

As such, when large gate resistor having several kΩ is connected to the gate terminal, a voltage drop occurs in the gate to which the resistor having several kΩ is connected due to the gate leakage current, thereby reducing power transfer capability of the SPDT switch.

### SUMMARY

Accordingly, the present invention provides a single pole double through (SPDT) switch in which an inductor is applied to a gate terminal of a GaN switching element to improve power transfer capability.

The above and other objects, advantages and features of the present invention, and a method for achieving them will become apparent with reference to the embodiments described below in detail in conjunction with the accompanying drawings.

In one general aspect, a single pole double through (SPDT) switch includes: a series switching unit including first and second series switching elements commonly connected to a common input port; and a shunt switching unit including a plurality of shunt switching elements connected in parallel to a first signal path connecting the common input port to a first output port and a second signal path connecting the common input port to a second output port, wherein first and second inductors are respectively connected to gate terminals of the first and second series switching elements.

The first and second inductors may be used to prevent a voltage drop occurring in the gate terminals of the first and second series switching elements due to a gate leakage current of the first and second series switching elements.

The first and second inductors may be implemented as rectangular spiral planar inductors on a substrate.

A resistor may be connected to gate terminals of the plurality of shunt switching elements.

The resistor may be a thin film resistor (TFR) extending in a zigzag line on a substrate.

The number of gate fingers of each of the first and second series switching elements may be greater than the number of gate fingers of each of the plurality of shunt switching elements.

The first and second series switching elements and the plurality of shunt switching elements may be gallium nitride-based field effect transistors.

The shunt switching unit may include a first shunt switching unit including a first shunt switching element connected in parallel to the first signal path and a second shunt switching element connected in parallel to the second signal path; and a third shunt switching element additionally connected in parallel to the first signal path and a fourth shunt switching element additionally connected in parallel to the second signal path.

The first shunt switching element and the third shunt switching element connected in parallel to the first signal path may be connected by a third inductor, and the second shunt switching element and the fourth shunt switching element connected in parallel to the second signal path may be connected by a fourth inductor.

The first shunt switching element, the third shunt switching element, and the third inductor may operate as a low pass filter for an input signal transferred through the first signal path, and

The second shunt switching element, the fourth shunt switching element, and the fourth inductor may operate as a low pass filter for an input signal transferred through the second signal path.

Other features and aspects will be apparent from the following detailed description, the drawings, and the claims.

### BRIEF DESCRIPTION OF THE DRAWINGS

FIG. 1 is a circuit configuration diagram of single pole double through (SPDT) switch designed using a switching element in which an inductor is connected to a gate terminal according to an embodiment of the present invention.

FIG. 2 is a schematic layout of the SPDT switch shown in FIG. 1.

FIG. 3 is a graph of measured characteristics of the SPDT switch shown in FIG. 1.

FIG. 4 is a graph of insertion loss measured according to input power of the SPDT switch shown in FIG. 1.

### DETAILED DESCRIPTION OF EMBODIMENTS

While a specific structural or functional description with respect to embodiments according to the present invention disclosed in this specification is merely provided for the purpose of describing the embodiments of the present invention, there are various modifications capable of replacing the embodiments, and the present invention is not limited to the embodiments described in this specification.

The terminology used herein is only used to describe specific embodiments and is not intended to limit the present invention.

In this disclosure, when it is mentioned that certain elements or lines are connected to a target device, it includes not only direct connection but also the meaning of indirectly connected to the target device through some other device.

A GaN switching element may be used as a switch as a channel resistance Rds between a source and a drain operates as a variable resistance according to a control voltage of the gate. Here, the source and drain are paths of an RF signal, and the gate is used as a control terminal.

In a case in which a voltage Vds between the source and the drain is 0V, when a control voltage Vg is controlled by 0V, a resistance value of the channel resistance Rds is reduced, and when the control voltage Vg is controlled by a voltage smaller than a pinch-off voltage from −3 to −5V, the channel resistance Rds increases and the GaN switching element operates as a variable resistor.

In general, in a GaN switching element, a resistance of several kδ may be connected to the gate of the GaN switching element (GaN FET) for sufficient isolation between a gate and a signal path between the source and the drain.

When input power input to a drain of the GaN switching element is increased in a state in which a resistance of several kΩ is connected to the gate of the GaN switching element, a voltage drop occurs at the gate due to the resistance of several kΩ connected to the gate terminal, causing a phenomenon in which the GaN switching element is turned off and the input power is not transmitted. This phenomenon does not occur in GaAs-based switching elements with little gate leakage current.

In order to prevent the GaN switching element from being turned off due to the gate leakage current, that is, in order to improve isolation between the signal path between the source and the drain and the gate, in the present invention, an SPDT switch is designed using a GaN switching element in which an inductor, instead of a resistor, is connected to a gate terminal.

When a resistor is connected to the gate terminal, the GaN switching element prevents leakage of RF signals from a low frequency band to a high frequency band to provide wideband characteristics.

When an inductor is connected to a gate terminal, a leakage of an RF signal in a low frequency band may not be effectively prevented, but if an inductor having an appropriate capacity is used in an actual frequency band, the inductor may be utilized, instead of a resistor, to improve isolation of the gate terminal from a signal path between the source and the drain.

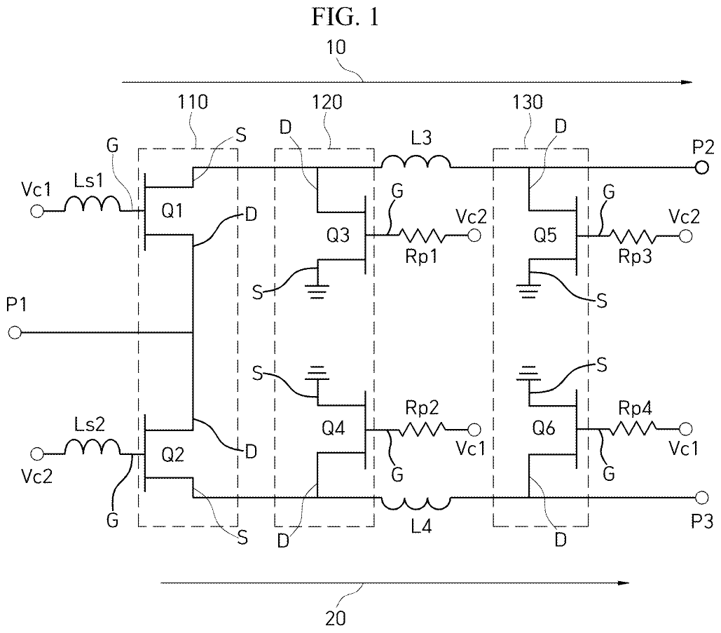

FIG. 1 is a circuit configuration diagram of an SPDT switch designed using a switching element in which an inductor is connected to a gate terminal according to an embodiment of the present invention.

Referring to FIG. 1, the SPDT switch according to an embodiment of the present invention is designed to have a series-parallel-parallel (series-shunt-shunt) structure. The series-shunt-shunt structure refers to a structure in which one switching element is connected in series to one signal path and two switching elements are connected in parallel. Here, a structure in which two switching elements are connected in parallel to a signal path is referred to as a ‘two-stage shunt structure’.

Switching elements having a two-stage shunt structure connect a signal path and a ground to allow a signal transmitted through an inactive signal path to be released to the ground, thereby improving isolation characteristics of the switching element.

Hereinafter, a switching element connected in series to a signal path is referred to as a ‘series switching element’, and a switching element connected in parallel to the signal path is referred to as a ‘shunt switching element’.

The SPDT switch having a series-shunt-shunt structure according to an embodiment of the present invention is a series switching unit 110, a first shunt switching unit 120, and a second shunt switching unit 130.

Series Switching Unit 110

The series switching unit 110 includes first and second series switching elements Q1 and Q2 commonly connected to the common input port P1, and the first and second series switching elements Q1 and Q2 may be, for example, GaN-based FETs in which a gate leakage current occurs, unlike a GaAs-based FET in which gate leakage current rarely occurs.

A drain terminal D of the first series switching element Q1 and a drain terminal D of the second series switching element Q2 are commonly connected to the common input port P1.

A passive element for isolating a gate terminal G from a signal path between the source S and the drain D of the first series switching element Q1 is connected to the gate terminal G of the first series switching element Q1. Here, the passive element may be an inductor Ls1.

Accordingly, a control voltage Vc1 for controlling a switching operation of the first series switching element Q1 is applied to the gate terminal G of the first series switching element Q1 through the first inductor Ls1.

Similarly, a passive element for isolating the gate terminal G from a signal path between a source S and a drain D of a second series switching element Q4 is connected to a gate terminal G of the second series switching element Q2. Here, the passive element may be an inductor Ls2.

Accordingly, a control voltage Vc2 for controlling a switching operation of the second series switching element Q2 is applied to the gate terminal G of the second series switching element Q2 through the second inductor Ls2.

In a related art, resistors are connected to the gate terminals of the first and second series switching elements Q1 and Q2, but in an embodiment of the present invention, the inductors Ls1 and Ls2 are connected to prevent a voltage drop of the gate terminal due to a gate leakage current occurring at the series switching elements Q1 and Q2 implemented as GaN-based FETs and improve power transfer capability of the SPDT switch.

Meanwhile, when the inductor is connected to the gate terminal, leakage of an RF signal (input power input through P1) at a low frequency band may not be effectively prevented.

However, if an inductor having a suitable capacity is used in an actual frequency band, the inductor may be sufficiently utilized instead of a resistor, for the purpose of improving isolation of the gate terminal from the signal path between the source and the drain.

First Shunt Switching Unit 120

The first shunt switching unit 120 includes a first shunt switching element Q3 and a second shunt switching element Q4, and each of the shunt switching elements Q3 and Q4 may be, for example, a GaN-based FET.

The first shunt switching element Q3 is connected in parallel to the first signal path 10 connecting the common input port P1 and the first output port P2, and the second shunt switching element Q4 is connected in parallel to the second signal path 20 connecting the common input port P1 and the second output port P3.

Specifically, a drain terminal D of the first shunt switching element Q3 is connected to the source terminal of the first series switching element Q1, and the source terminal S of the first shunt switching element Q3 is connected to ground.

A first resistor Rp1 is connected to a gate terminal G of the first shunt switching element Q3, and a control voltage Vc2 for controlling a switching operation of the first shunt switching element Q3 is applied to the gate terminal G through the first resistor Rp1.

A drain terminal D of the second shunt switching element Q4 is connected to the source terminal S of the second series switching element Q2, and the source terminal S is connected to the ground.

A second resistor Rp2 is connected to a gate terminal G of the second shunt switching element Q4, and a control voltage Vc1 for controlling a switching operation of the second shunt switching element Q4 is applied to the gate terminal G through the second resistor Rp2.

Second Shunt Switching Unit 130

The second shunt switching unit 130 may include a third shunt switching element Q5 and a fourth shunt switching element Q6, and each of the shunt switching elements Q5 and Q6 may be, for example, a GaN-based FET.

The third shunt switching element Q5 is connected in parallel to the first signal path 10, and the fourth shunt switching element Q6 is connected in parallel to the second signal path 20.

Specifically, a drain terminal D of the third shunt switching element Q5 is connected to the drain terminal D of the first shunt switching element Q3 through the third inductor L3, and a source terminal S of the third shunt switching element Q5 is connected to the ground.

A third resistor Rp3 is connected to a gate terminal G of the third shunt switching element Q5, and a control voltage Vc2 for controlling a switching operation of the third shunt switching element Q5 is applied to the gate terminal G through the third resistor Rp3.

A drain terminal D of the fourth shunt switching element Q6 is connected to the drain terminal D of the second shunt switching element Q4 through a fourth inductor L4, and a source terminal S of the fourth shunt switching element Q4 is connected to the ground.

A fourth resistor Rp4 is connected to a gate terminal G of the fourth shunt switching element Q6, and a control voltage Vc1 for controlling a switching operation of the fourth shunt switching element Q6 is applied to the gate terminal G through the fourth resistor Rp4.

Hereinafter, an operation process of the SPDT switch shown in FIG. 1 will be described.

Description of Operation

First, the control voltages Vc1 and Vc2 applied to the gate terminal G of each switching element have different logic levels. For example, when the control voltage Vc1 is a logic high level voltage (e.g., 0V), the control voltage Vc2 is a logic low level voltage (e.g., −40V), and conversely, when the control voltage Vc1 is a logic low level voltage (e.g., −40V), the control voltage Vc2 is a logic high level voltage (e.g., 0V).

When the control voltage Vc1 is a voltage of a logic high level and the control voltage Vc2 is a voltage of a logic low level, the first series switching element Q1, the second shunt switching element Q4, and the fourth shunt switching element Q6 are turned on, and the second series switching element Q2, the first shunt switching element Q3, and the third shunt switching element Q5 are turned off. Accordingly, the signal path 10 connecting the common input port P1 and the first output port P2 is activated.

Conversely, when the control voltage Vc1 is a voltage of a logic low level and the control voltage Vc2 is a voltage of a logic high level, the first series switching element Q1, the second shunt switching element Q4, and the fourth shunt switching element Q6 are turned off and the second series switching element Q2, the first shunt switching element Q3, and the third shunt switching element Q5 are turned on. Accordingly, the second signal path 20 connecting the common input port P1 and the second output port P3 is activated.

When the first signal path 10 is activated, as described above, Q1, Q4, and Q6 are in an “ON” state, Q2, Q3, and Q5 are in an “OFF” state, Q3 and Q5 in the OFF state operate as capacitors and operates as a low pass filter together with the inductor L3 connecting Q3 and Q5.

Here, since Q2 is in the OFF state, input power input through the common input port P1 should not be transferred to the second output port P3, but due to parasitic capacitance of the second series switching element Q2, the input power may be transferred to the second output port P3. However, since Q4 and Q6 are in the ON state, the input signal is not transmitted to the second output port P3 but exits to the ground.

As such, the shunt switching elements Q4 and Q6 connected in parallel to the signal path 10 serve to improve isolation between the signal path 10 and the signal path 20.

Meanwhile, as the input power input through the common input port (P1) increases, a gate leakage current generated in the first series switching element Q1 in the ON state increases. However, in the present invention, even if the gate leakage current increases, by connecting the inductor Ls1 to the gate terminal of the first series switching element Q1 instead of the resistor, the voltage drop occurring at the gate terminal due to the gate leakage current is prevented, thereby preventing the first series switching element Q1 from being switched from the ON state to the OFF state. Accordingly, maximum power that can be provided with the size of the first series switching element Q1 may be transmitted.

For simplicity of description, the operation process when the signal path 20 is activated is replaced with the description of the operation process described above when the signal path 10 is activated.

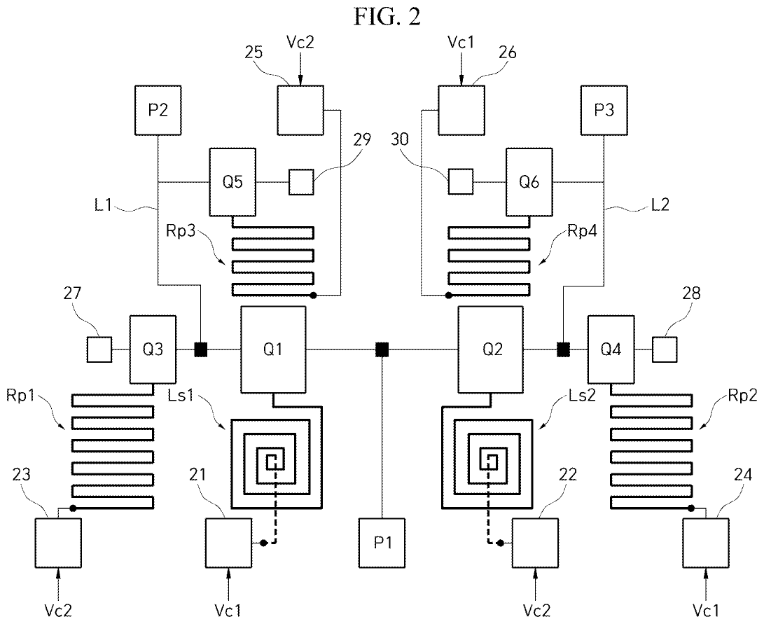

FIG. 2 is a schematic layout of the SPDT switch shown in FIG. 1.

Referring to FIG. 2, the components of the SPDT switch according to an embodiment of the present invention may be embedded in a substrate in which a plurality of layers are stacked, disposed on different layers, and electrically connected through a via hole.

The components of the SPDT switch, as shown in FIG. 2, are arranged in a symmetrical form, and transmission lines and ports connecting the components may be mainly patterned on a surface of the substrate.

Reference numerals 21 to 26 are voltage ports providing the control voltages Vc1 and Vc2 to the gate terminals of the switching elements Q1 to Q6 shown in FIG. 1 and are patterned to be disposed nearby in the layout. Reference numerals 27 to 30 are ground ports.

The common input port P1 may be disposed at a lower portion in the middle of the layout, and the two output ports P2 and P3 may be disposed at the upper portions on the left and right on the layout.

Although not clearly shown in FIG. 2, for the convenience of performance testing of the SPDT, the voltage ports 21, 24 and 26 providing the control voltage Vc1 may be connected in one line, and the voltage ports 22, 23, and 25 providing the control voltage Vc2 may be connected to the other line.

The control voltage Vc1 is applied to the gate terminals of Q1, Q4 and Q6 through voltage ports 21, 24 and 26, respectively, and the control voltage Vc2 is applied to the gate terminals of Q2, Q3, and Q5 through the voltage ports 22, 23 and 25, respectively.

Meanwhile, the gate terminal of Q1 and the voltage port 21 are connected by a first inductor Ls1, and the gate terminal of Q2 and the voltage port 22 are connected by a second inductor Ls2, and here, the first and second inductors Ls1 and Ls2 may be implemented as rectangular spiral planar inductors as shown in FIG. 2.

The gate terminal of Q3 and the voltage port 23 are connected by the first resistor Rp1, the gate terminal of Q4 and the voltage port 24 are connected by a second resistor Rp2, and the gate terminal of Q5 and the voltage port 25 are connected by the third resistor Rp3. Also, the gate terminal of Q6 and the voltage port 26 are connected by the fourth resistor Rp4.

The first to fourth resistors Rp1 to Rp4 may be implemented as thin film resistors (TFRs) extending in zigzag lines as shown in FIG. 2.

A transmission line connecting the drain terminal of Q3 and the drain terminal of Q5 serves as the inductor L1 of FIG. 1, and a transmission line connecting the drain terminal of Q4 and the drain terminal of Q6 serves as the inductor L2 of FIG. 1.

Hereinafter, performance test results of the SPDT switch according to an embodiment of the present invention will be described.

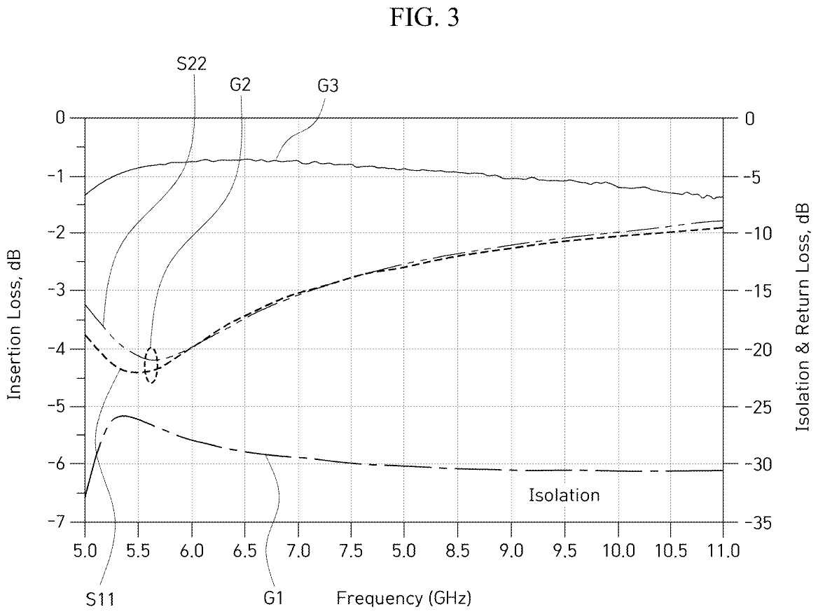

FIG. 3 is a graph showing measured characteristics of the SPDT switch shown in FIG. 1.

First, the specification of the SPDT switch manufactured for the performance test is as follows.

TABLE 1

| | | Series | Shunt | | | | Resis- |
|---|---|---|---|---|---|---|---|
| | | FET | FET | Fre- | | Induc- | tor |
| | | (Q1, | (Q3~ | quency | Control | tor | (Rp1~ |
| Process | Size | Q2) | Q6) | band | voltage | (Ls) | Rp4) |
| 0.2 μm | 1.3 | 7F100 | 3F50 | X band | Vc1: | 3.5 nH | 3 kΩ |
| GaN | mm × | | | | 0 V | | |
| process | 1.55 | | | | Vc2: | | |
| | mm | | | | −40 V | | |

In the SPDT switch for the performance test, a series FET of 7F100 and a shunt FET of 3F75 are used to enable power transfer of 20 W class. Here, 7F100 is a symbol indicating a size of the series FETs Q1 and Q2, meaning that the number of gate fingers is 7 and a width of the entire gates including 7 gates is 100 μm.

3F50 is a symbol indicating a size of the shunt FET, meaning that the number of gate fingers is 3 and a width of the entire gate including three gates is 50 μm.

The test was conducted for three items of insertion loss, return loss and isolation of the SPDT switch.

The insertion loss and return loss tests were conducted at 0 V Vc1 and −40 V Vc2, and the isolation test was performed at −40 V Vc1 and 0 V Vc2.

The test results are the same as the graphs G1, G2, and G3 shown in FIG. 3. In FIG. 3, the horizontal axis represents frequency (GHz), and the right side of the vertical axis represents isolation and return loss in dB. The left side of the vertical axis represents the insertion loss in dB.

As shown in graph G3, the insertion loss has a value of 1.18 dB or less in the 8 to 10 GHz band. As shown in graph G2, the return loss has a value of 9.8 dB or less in the same band. S11 and S22 represent reflective coefficients in S-parameters. An expression value of the reflective coefficient in dB is the return loss. As can be seen from graph G1, isolation has a value of 30.1 dB or higher in the same band. Therefore, it can be confirmed that the SPDT switch according to an embodiment of the present invention provides excellent RF switching performance in the high-frequency band of the 8 to 10 GHz band.

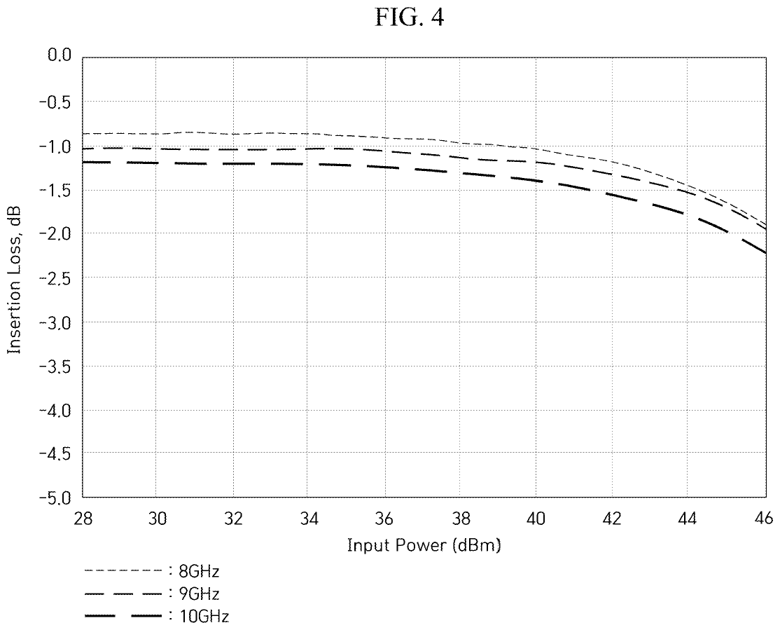

FIG. 4 is a graph illustrating insertion loss measured according to input power of the SPDT switch shown in FIG. 1.

Maximum input power characteristics of the SPDT switch according to an embodiment of the present invention is the same as the graphs shown in FIG. 4, and the insertion loss test according to input power was conducted with input power of 45.5 dBm (35 W) or higher and output power of 43.5 dBm (22 W) or higher in 8 to 10 GHz band.

As described above, the applicant successfully designed, fabricated and tested an X-band 20 W class GaN SPDT switch using a GaN process.

As described above, in the present invention, by connecting an inductor, instead of a resistor, to the gate terminals of the series FETs Q1 and Q2, a gate voltage drop due to a gate leakage current of the series FETs Q1 and Q2 occurring at large RF input power may be prevented and power may be transferred with maximum power that can be provided in the size of the series FET.

According to the present invention, when designing an SPDT switch using a GaN-based switching element, an inductor is connected to a gate terminal of the switching element, instead of a resistor, to prevent a voltage drop occurring at the gate terminal due to a gate leakage current, thereby transferring power with the maximum power transfer capability that can be provided in an area of the switching element.

The present invention may be equally applied to switches having various structures such as single pole single throw (SPST) switches and single pole 3 throw (SP3T) switches, as well as SPDT switches.

A number of exemplary embodiments have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. A single pole double through (SPDT) switch comprising:
a series switching unit including first and second series switching elements commonly connected to a common input port; and
a shunt switching unit including a plurality of shunt switching elements connected in parallel to a first signal path connecting the common input port to a first output port and a second signal path connecting the common input port to a second output port,
wherein first and second inductors are respectively connected to gate terminals of the first and second series switching elements.

2. The SPDT switch of claim 1, wherein the first and second inductors are used to prevent a voltage drop occurring in the gate terminals of the first and second series switching elements due to a gate leakage current of the first and second series switching elements.

3. The SPDT switch of claim 1, wherein the first and second inductors are implemented as rectangular spiral planar inductors on a substrate.

4. The SPDT switch of claim 1, wherein a resistor is connected to gate terminals of the plurality of shunt switching elements.

5. The SPDT switch of claim 4, wherein the resistor may be a thin film resistor (TFR) extending in a zigzag line on a substrate.

6. The SPDT switch of claim 1, wherein a number of gate fingers of each of the first and second series switching elements is greater than a number of gate fingers of each of the plurality of shunt switching elements.

7. The SPDT switch of claim 1, wherein the first and second series switching elements and the plurality of shunt switching elements are gallium nitride-based field effect transistors.

8. The SPDT switch of claim 1, wherein
the shunt switching unit includes:
a first shunt switching unit including a first shunt switching element connected in parallel to the first signal path and a second shunt switching element connected in parallel to the second signal path; and
a third shunt switching element additionally connected in parallel to the first signal path and a fourth shunt switching element additionally connected in parallel to the second signal path.

9. The SPDT switch of claim 8, wherein the first shunt switching element and the third shunt switching element connected in parallel to the first signal path are connected by a third inductor, and the second shunt switching element and the fourth shunt switching element connected in parallel to the second signal path are connected by a fourth inductor.

10. The SPDT switch of claim 9, wherein the first shunt switching element, the third shunt switching element, and the third inductor operate as a low pass filter for an input signal transferred through the first signal path, and the second shunt switching element, the fourth shunt switching element, and the fourth inductor operate as a low pass filter for an input signal transferred through the second signal path.
